(19) United States
(12) Patent Application Publication
(10) Pub. No.: US 2026/0133237 A1
(43) Pub. Date: May 14, 2026

(54) METHOD FOR IDENTIFYING AND POSITIONING PARTIAL DISCHARGE OF HIGH-VOLTAGE CABLE

(71) Applicant: LANDPOWER WUHAN CO., LTD., Wuhan (CN)

(72) Inventors: Yong Chen, Wuhan (CN); Yongjun Wang, Wuhan (CN); Qian Hao, Wuhan (CN); Wenxiong Huang, Wuhan (CN); Wen Wang, Wuhan (CN); Pan Yuan, Wuhan (CN)

(21) Appl. No.: 19/385,291

(22) Filed: Nov. 11, 2025

(30) Foreign Application Priority Data
Nov. 14, 2024 (CN) 2024116224237

(51) Int. Cl. G01R 31/08; G01R 31/12

(52) U.S. Cl. CPC G01R 31/088; G01R 31/1272

(57) ABSTRACT

Provided is a method for identifying and positioning partial discharge of a high-voltage cable, which includes: collecting a partial discharge pulse signal; performing noise reduction processing on the partial discharge pulse signal to obtain a denoised partial discharge characteristic signal; inputting the denoised partial discharge characteristic signal into a pre-trained lightweight residual attention network to output a discharge type discrimination result, a discharge intensity, and characteristic parameters; and using, based on the discharge type discrimination result, the discharge intensity, and the characteristic parameters, a self-correcting dual-end localization algorithm to position a discharge source, including: measuring a time difference of arrival of the partial discharge pulse signal at the two ends of the high-voltage cable, and calculating, based on the time difference, the discharge type discrimination result, the discharge intensity, the characteristic parameters, and a length parameter of the high-voltage cable, a position of the discharge source.

### CROSS-REFERENCE TO RELATED APPLICATION

This application claims priority to Chinese Patent Application No. 202411622423.7, filed on Nov. 14, 2024, which is herein incorporated by reference in its entirety.

### TECHNICAL FIELD

The present disclosure relates to the technical field of high-voltage cable diagnostics, and more particularly to a method for identifying and positioning partial discharge of a high-voltage cable.

### BACKGROUND

High-voltage cables are key components of power systems, and safe operation of the high-voltage cables directly affects the reliability of power supply. The high-voltage cables are defined as cables used for power transmission at voltages of 35 kV and higher. Partial discharge is an important indicator of insulation deterioration in a high-voltage cable, and is capable of revealing a type, a position, and severity of an insulation defect. Therefore, accurate type recognition and precise localization of the partial discharge are essential for preventing cable failures and ensuring secure grid operation.

Existing identification techniques for the partial discharge mainly rely on signal-processing and pattern-recognition methods. For signal processing, methods such as wavelet transform and empirical-mode decomposition are adopted for de-noising and feature extraction; for discharge-type classification, pattern recognition is mainly based on phase spectrum characteristics and pulse waveform features, such as cluster analysis based on statistical parameters and feature extraction based on phase distribution map. For discharge source localization, a single-ended localization method and a dual-end localization method are primarily used, in which the dual-end localization method calculates a position of a discharge point by measuring a time difference of a discharge signal arriving at two ends of a cable, which offers relatively high localization accuracy.

However, there are still the following problems in the prior art. Firstly, a traditional signal processing method has unsatisfactory noise reduction effect and limited feature extraction ability in a complex electromagnetic environment. Secondly, a recognition method based on preset features is difficult to adapt to differences of different types of a discharge signal, and a corresponding recognition accuracy is limited. Thirdly, existing positioning algorithms often ignore the influence of cable parameters and environmental factors on signal propagation characteristics in practical application, which leads to unstable positioning accuracy. In addition, due to the lack of systematic signal processing and analysis methods, it is difficult to achieve accurate extraction and reliable judgment of discharge characteristics, which restricts the further development of detection technology.

### SUMMARY

In view of this, the present disclosure provides a method for identifying and positioning partial discharge of a high-voltage cable. By adopting an adaptive multi-scale wavelet decomposition and reconstruction method to denoise a discharge signal, and using a lightweight residual attention network to achieve the accurate identification of a discharge type, and using a self-correcting dual-end localization algorithm to achieve the accurate positioning of a discharge source, the present disclosure solve the technical problems of unsatisfactory signal noise reduction effect, lower accuracy of discharge type identification, unstable positioning accuracy in the prior art, thereby realizing high-precision identification and positioning of the partial discharge of the high-voltage cable.

Technical solutions of the present disclosure are as follows.

A method for identifying and positioning partial discharge of a high-voltage cable is provided, which includes the following steps:
S1, collecting, by high-frequency current transformers respectively disposed two ends of the high-voltage cable, a partial discharge pulse signal;
S2, performing noise reduction processing on the partial discharge pulse signal by using an adaptive multi-scale wavelet decomposition and reconstruction method to obtain a denoised partial discharge characteristic signal;
S3, inputting the denoised partial discharge characteristic signal into a pre-trained lightweight residual attention network for identification and classification to thereby output a discharge type discrimination result, a discharge intensity, and characteristic parameters, where the lightweight residual attention network includes a parallel multi-scale decomposition module, a frequency-domain guided attention module, a characteristic adaptive fusion module, and an output module; and
S4, using, based on the discharge type discrimination result, the discharge intensity, and the characteristic parameters, a self-correcting dual-end localization algorithm to position a discharge source, specifically including: measuring a time difference of arrival of the partial discharge pulse signal at the two ends of the high-voltage cable, and calculating, based on the time difference, the discharge type discrimination result, the discharge intensity, the characteristic parameters, and a length parameter of the high-voltage cable, a position of the discharge source.

In an embodiment, the method further includes: removing, by using a hydraulic cable cutter, a faulty section of the high-voltage cable at the position of the discharge source to define a gap; performing peeling, grinding, cleaning, and crimping pretreatment on two exposed ends of high-voltage cable, and installing a prefabricated straight-through joint at the gap to ensure normal operation of the high-voltage cable.

In an embodiment, the method further includes: based on the position of the discharge source, guiding an on-site operator to cut and repair a faulty section of the high-voltage cable at the position of the discharge source. Therefore, through precise positioning, a length to be cut of the high-voltage cable and a scope of power outage are reduced, thereby shortening the fault repair time and improving the power supply reliability of an electrical system.

In an embodiment, the step S2 includes:
S21, determining a wavelet basis function for the partial discharge pulse signal;
S22, performing, by using the wavelet basis function, n-level wavelet decomposition on the partial discharge pulse signal to obtain an approximation coefficient an and detail coefficients d₁-dₙ;
S23, calculating a signal-to-noise ratio SNRⱼ for a detail coefficient corresponding to each of n levels based on the following formula:

$${SNR}_{j} = 10 {log}_{10} ( \frac{{σ}_{sj}^{2}}{{σ}_{nj}^{2}} )$$

where

$${σ}_{sj}^{2}$$

represents a signal variance

$${σ}_{nj}^{2}$$

represents a noise variance, j represents a decomposition level number, and j=1, 2, . . . , n;

S24, establishing an adaptive weight coefficient calculation model, where the adaptive weight coefficient calculation model is expressed as follows:

$${w}_{j} = \frac{{SNR}_{j}}{max ( {SNR}_{1} , {SNR}_{2} , … , {SNR}_{n} )}$$

where wⱼ represents an adaptive weight coefficient; and

S25, performing, based on the adaptive weight coefficient of each level and the detail coefficient of each level and according to a reconstruction signal model, wavelet reconstruction to obtain the denoised partial discharge characteristic signal, where the reconstruction signal model is expressed as follows:

$$Y ( t ) = \sum ( {w}_{j} \cdot {T}_{j} ( {d}_{j} ) )$$

where Y(t) represents a reconstructed signal, and Tⱼ(dⱼ) represents a threshold function.

In an embodiment, the threshold function Tⱼ(dⱼ) is a soft threshold function, and the soft threshold function is expressed as follows:

$${T}_{j} ( {d}_{j} ) = sign ( {d}_{j} ) ( \vert {d}_{j} \vert - {λ}_{j} ) , \vert {d}_{j} \vert > {λ}_{j}$$

$${T}_{j} ( {d}_{j} ) = 0 , \vert {d}_{j} \vert \leq {λ}_{j}$$

where λⱼ represents an adaptive threshold for a j-th level, and a formula for λⱼ is expressed as follows:

$${λ}_{j} = {σ}_{j} \cdot {( 2 ln N )}^{0.5}$$

where σ_{g} represents a noise standard deviation for the j-th level, and N represents a signal length.

In an embodiment, the step S2 further includes:
determining an optimal decomposition scale n based on signal frequency features of the partial discharge pulse signal, where a calculation formula for the optimal decomposition scale n is expressed as follows:

$$n = floor ( {log}_{2} ( \frac{{f}_{s}}{{f}_{m i n}} ) )$$

where fₛ represents a sampling frequency, fₘᵢₙ represents a lowest frequency of interest, and floor represents a floor function.

In an embodiment, the lightweight residual attention network includes: a parallel multi-scale decomposition module, where the parallel multi-scale decomposition module includes three parallel branches, the three parallel branches are a first branch, a second branch, and a third branch, and each of the three parallel branches includes two depthwise separable convolutional residual blocks; the first branch has a 3×3 convolution kernel, a stride of 1, and 64 channels; the second branch has a 5×5 convolution kernel, a stride of 1, and 32 channels; the third branch has a 7×7 convolution kernel, a stride of 1, and 16 channels; and each of the two depthwise separable convolutional residual blocks of each of the three parallel branches includes two layers of depthwise separable convolution and one skip connection;
a frequency-domain guided attention module, including: an input layer, two fully connected layers, and an attention weight calculation layer;
a characteristic adaptive fusion module, including: an energy distribution calculation unit, configured to calculate an energy distribution of each of characteristic maps of the three parallel branches; an adaptive weight generation unit, configured to output fusion weights of the three parallel branches; and a feature fusion unit, configured to perform a concatenate operation on weighted features; and
an output module, including three task branches, where the three task branches are a discharge type branch, a discharge intensity branch, and a characteristic parameter branch, and each of the three task branches includes two fully connected layers.

In an embodiment, a process for processing the partial discharge characteristic signal by the lightweight residual attention network includes:
inputting the partial discharge characteristic signal into the parallel multi-scale decomposition module, processing, by the three parallel branches, the partial discharge characteristic signal simultaneously, and outputting, by each of the three parallel branches, a corresponding one characteristic map of the characteristic maps with a corresponding scale;
inputting the characteristic maps outputted by the parallel multi-scale decomposition module into the frequency-domain guided attention module; calculating, by the input layer of the frequency-domain guided attention module, a spectral characteristic through fast Fourier transform; extracting, by the two fully connected layers of the frequency-domain guided attention module, a frequency domain feature, where output dimensions of the two fully connected layers are 128 and 64, respectively; generating, by the attention weight calculation layer, attention weights and outputting a weight matrix with the same dimensions as the input characteristic maps; and weighting, by the attention weight calculation layer, the characteristic maps based on the weight matrix to obtain weighted characteristic maps;
inputting the weighted characteristic maps into the characteristic adaptive fusion module, calculating, by the characteristic adaptive fusion module, a feature energy of each of the characteristic maps of the three parallel branches, calculating, by the characteristic adaptive fusion module, the fusion weights based on the feature energy of each of the characteristic maps, and performing, by the characteristic adaptive fusion module, weighted fusion to obtain a final feature representation; and
using the final feature representation as a shared feature, inputting the shared feature into the output module, and processing the shared feature through the three task branches of the output module, respectively, where the processing the shared feature through the three task branches of the output module includes:
for the discharge type branch: inputting the shared feature into a first fully connected layer with 128 neurons of the discharge type branch to obtain a first output result, using a rectified linear unit (ReLU) function of the discharge type branch to activate the first output result to obtain a first activated result, inputting the first activated result into a second fully connected layer with a total number of neurons equal to a total number of discharge types of the discharge type branch to obtain a second output result, using a softmax function of the discharge type branch to activate the second output result to obtain a second activated result to output a probability distribution of each of the discharge types, and determining a discharge type with a highest probability of the discharge types is determined as the discharge type discrimination result;
for the discharge intensity branch: inputting the shared feature into a first fully connected layer with 128 neurons of the discharge intensity branch to obtain a third output result, using an ReLU function of the discharge intensity branch to activate the third output result to obtain a third activated result, inputting the third activated result into a second fully connected layer with a single neuron of the discharge intensity branch to obtain a fourth output result, and using a linear activation function of the discharge intensity branch to activate the fourth output result to obtain an intensity value as the discharge intensity; and
for the characteristic parameter branch: inputting the shared feature into a first fully connected layer with 128 neurons of the characteristic parameter branch to obtain a fifth output result, using an ReLU function of the characteristic parameter branch to activate the fifth output result to obtain a fifth activated result, inputting the fifth activated result into a second fully connected layer with a total number of neurons equal to a total number of characteristic parameters of the characteristic parameter branch to obtain a sixth output result, and using a linear activation function of the characteristic parameter branch to activate the sixth output result to obtain parameter values as the characteristic parameters.

In an embodiment, the step S4 includes:
S41, determining propagation speed correction coefficients according to the discharge type discrimination result, and correcting, based on the propagation speed correction coefficients and a discharge intensity coefficient, a propagation speed;
S42, establishing, based on a main frequency feature, an amplitude feature and a waveform feature of the partial discharge pulse signal, a signal propagation model considering multi-factor influences to calculate a comprehensive correction term;
S43, acquiring, by a global positioning system (GPS) high-precision time synchronization system, timestamps of the partial discharge pulse signal arrival at the two ends of the high-voltage cable, calculating, based on the timestamps, a maximum value point of a cross-correlation function of signals collected at the two ends to obtain a precise time difference; and
S44, calculating the position of the discharge source based on the length parameter of the high-voltage cable, the corrected propagation speed, and the precise time difference.

In an embodiment, a formula for correcting the propagation speed is expressed as follows:

$$v = {v}_{0} \cdot ( 1 + {k}_{1} \cdot type + {k}_{2} \cdot strength )$$

where ν represents a corrected propagation speed, ν₀ represents a theoretical propagation speed of the partial discharge pulse signal in the high-voltage cable, k₁ represents a discharge type correction coefficient, k₂ represents a discharge intensity correction coefficient, type represents a discharge type coefficient, and strength represents a discharge intensity coefficient;
where a calculation formula for the precise time difference is expressed as follows:

$$τ = arg max \{ {R}_{12} ( t ) \}$$

where τ represents the precise time difference, R₁₂(t) represents the cross-correlation function of the signals at the two ends of the high-voltage cable, R₁₂(t)=∫x₁(τ)x₂(τ−t)dτ, x₁(τ) represents a signal collected at a first end of the two ends, x₂(τ) represents a signal collected at a second end of the two ends, t represents a time delay value to be tried, and x₂(τ−t) represents a signal obtained by moving the signal collected at the second end to the right by t time units;
where a calculation formula for the comprehensive correction term is expressed as follows:

$$δ = α \cdot freq + β \cdot amp + γ \cdot shape$$

where δ represents the comprehensive correction term, freq represents the main frequency feature of the partial discharge pulse signal, amp represents the amplitude feature of the partial discharge pulse signal, shape represents the waveform feature of the partial discharge pulse signal, and α, β, and γ are weight coefficients of the main frequency feature, the amplitude feature, and the waveform feature, respectively; and
where a calculation formula for the position of the discharge source is expressed as follows:

$$d = \frac{L + τ \cdot v}{2} + δ$$

where d represents a distance from a partial discharge point to a reference end, and L represents a total length of the high-voltage cable.

In an embodiment, the discharge type discrimination result is one of three categories: internal discharge, surface discharge, and corona discharge; and a value of the discharge type coefficient type is 1.0 for the internal discharge, is 0.8 for the surface discharge, or is 0.6 for the corona discharge;
where a calculation formula for the discharge intensity coefficient strength is expressed as follows:

$$strength = min ( 1. , q / {q}_{0} )$$

where q represents an actual discharge intensity, and q₀ represents a theoretical discharge intensity threshold.

In an embodiment, each of the high-frequency current transformers has a sampling resolution of 14 bits, a sampling frequency of 10 mega samples per second (MS/s)−100 MS/s, and a sampling bandwidth of 0.01 MHz-10 MHz.

Compared with the prior art, the present disclosure has at least the following beneficial effects.
(1) The present disclosure constructs a complete technical system of partial discharge identification and position of high-voltage cables, realizes high-precision signal acquisition through high-frequency current transformers, and organically integrates adaptive multi-scale wavelet decomposition and noise reduction, lightweight residual attention network identification and self-tuning double-terminal position algorithms. The technical system realizes the automatic processing of the whole process from signal acquisition, feature extraction to type identification and position, and improves the recognition accuracy and position accuracy of partial discharge detection.
(2) The adaptive multi-scale wavelet decomposition and reconstruction method of the present disclosure realizes dynamic optimization of decomposition coefficients in different frequency bands by introducing an adaptive weight calculation model based on signal-to-noise ratios. This method can automatically adjust the weight coefficient of each scale according to the signal characteristics, and effectively suppress the background noise while maintaining the integrity of the effective signal.
(3) The lightweight residual attention network designed by the present disclosure adopts the combined structure of the parallel multi-scale decomposition module, the frequency-domain guided attention module and the characteristic adaptive fusion module, and realizes accurate capture and classification of different types of discharge signal features through multi-scale feature extraction, frequency-domain energy distribution analysis and feature dynamic fusion. The network structure can effectively improve the accuracy of discharge type identification while reducing the computational complexity.
(4) The self-correcting dual-end localization algorithm of the present disclosure establishes a multi-factor modified signal propagation model, and realizes the self-adaptive correction of propagation speed by introducing the discharge type coefficient and the discharge intensity coefficient and combining the comprehensive influence of signal characteristic parameters. The algorithm cooperates with GPS high-precision time synchronization system, which effectively improves the accuracy of the positioning of the discharge source and provides a reliable position basis for troubleshooting.

### BRIEF DESCRIPTION OF DRAWINGS

In order to more clearly explain embodiments of the present disclosure or the technical solutions in the prior art, accompanying drawings needed to be used in the description of the embodiments or the prior art will be briefly introduced below. Apparently, the drawings in the following description are only some embodiments of the present disclosure, and other drawings can be obtained according to these drawings without creative work for ordinary people in the field.

FIG. 1 illustrates a schematic flowchart of a method for identifying and positioning partial discharge of a high-voltage cable according to an embodiment of the present disclosure.

FIG. 2 illustrates a schematic structural view of a lightweight residual attention network according to an embodiment of the present disclosure.

### DETAILED DESCRIPTION OF EMBODIMENTS

In the following, technical solutions in embodiments of the present disclosure will be clearly and completely described in combination with the embodiments of the present disclosure. Apparently, the described embodiments are only part of embodiments of the present disclosure, but not the whole. Based on the described embodiments in the present disclosure, all other embodiments obtained by ordinary technicians in the field without creative labor belong to the scope of protection of the present disclosure.

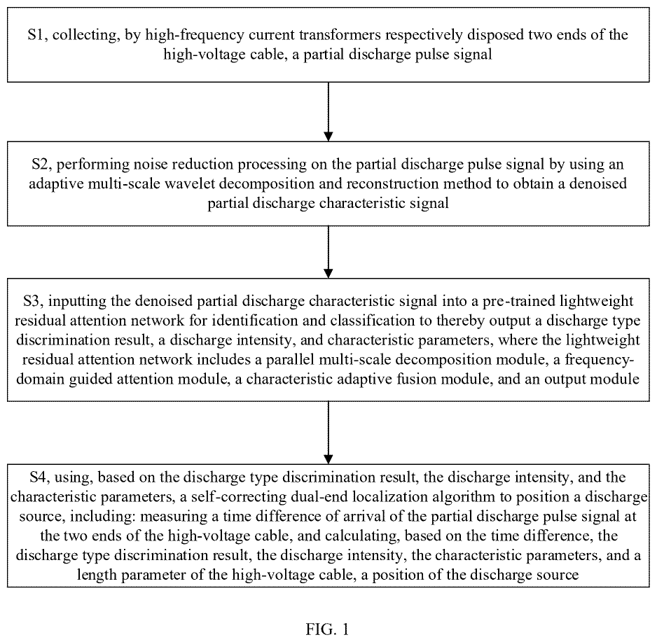

As shown in FIG. 1, a method for identifying and positioning partial discharge of a high-voltage cable is provided according to an embodiment of the present disclosure, which includes the following steps S1 to S4.

In the step S1, a partial discharge pulse signal is collected by high-frequency current transformers respectively disposed at two ends of the high-voltage cable.

In the step S2, noise reduction processing is performed on the partial discharge pulse signal by using an adaptive multi-scale wavelet decomposition and reconstruction method to obtain a denoised partial discharge characteristic signal.

In the step S3, the denoised partial discharge characteristic signal is inputted into a pre-trained lightweight residual attention network for identification and classification to thereby output a discharge type discrimination result, a discharge intensity, and characteristic parameters. The lightweight residual attention network includes a parallel multi-scale decomposition module, a frequency-domain guided attention module, a characteristic adaptive fusion module, and an output module.

In the step S4, based on the discharge type discrimination result, the discharge intensity and the characteristic parameters, a self-correcting dual-end localization algorithm is used to position a discharge source, specifically, a time difference of arrival of the partial discharge pulse signal at the two ends of the high-voltage cable is measured, and a position of the discharge source is calculated based on the time difference, the discharge type discrimination result, the discharge intensity, the characteristic parameters, and a length parameter of the high-voltage cable.

In the method for identifying and positioning partial discharge of the high-voltage cable provided by the present disclosure, the partial discharge pulse signal is firstly collected through the high-frequency current transformers disposed at the two ends of the high-voltage cable. Then, the adaptive multi-scale wavelet decomposition and reconstruction method is used to perform noise reduction processing on the collected partial discharge pulse signal.

This adaptive multi-scale wavelet decomposition and reconstruction method selects an appropriate wavelet basis function to perform n-level wavelet decomposition on the partial discharge pulse signal to obtain an approximation coefficient and detail coefficients. An adaptive weight coefficient model is established based on signal-to-noise ratios (SNRs), and a soft threshold function is used for signal reconstruction to obtain the denoised partial discharge characteristic signal. Subsequently, the denoised partial discharge characteristic signal is input into the pre-trained lightweight residual attention network for identification and classification. The pre-trained lightweight residual attention network includes: a parallel multi-scale decomposition module, which includes three parallel branches with different convolution kernel sizes; a frequency-domain guided attention module, which includes an input layer, fully connected layers, and an attention weight calculation layer; a characteristic adaptive fusion module, which includes an energy distribution calculation unit, an adaptive weight generation unit, and a feature fusion unit; and an output module, which includes three task branches. The three task branches of the output module are respectively configured to output the discharge type discrimination result (internal discharge, surface discharge, or corona discharge), the discharge intensity, and the characteristic parameters. Finally, based on the discharge type discrimination result, the discharge intensity, and the characteristic parameters, a self-correcting dual-end localization algorithm is used to position a discharge source. The self-correcting dual-end localization algorithm comprehensively considers combined influence of a discharge type coefficient, a discharge intensity coefficient, and signal characteristics (i.e., a main frequency, an amplitude, and a waveform), specifically, in the self-correcting dual-end localization algorithm, based on timestamps of arrival of the partial discharge pulse signal at the two ends of the high-voltage cable collected by a global positioning system (GPS) high-precision time synchronization system, a maximum value point of a cross-correlation function of signals collected at the two ends of the high-voltage cable is calculated to obtain a precise time difference. A position of the discharge source is then calculated based on the precise time difference, a length parameter of the high-voltage cable, and a corrected propagation speed, thereby achieving precise localization of the partial discharge of the high-voltage cable.

In an embodiment, each of the parallel multi-scale decomposition module, the frequency-domain guided attention module, the characteristic adaptive fusion module, and the output module is software configured to be stored in at least one memory and executable by at least one processor coupled to the at least one memory. Each of the energy distribution calculation unit, the adaptive weight generation unit, and the feature fusion unit is software configured to be stored in at least one memory and executable by at least one processor coupled to the at least one memory.

Specifically, in an embodiment of the present disclosure, in the step S1, two high-frequency current transformers are respectively installed at the two ends of the high-voltage cable to collect a high-frequency pulse current signal generated by the partial discharge of the high-voltage cable. A sampling accuracy of each of the two high-frequency current transformers is 14 bits, a sampling frequency of each of the two high-frequency current transformers may be adjusted in a range of 10-100 mega samples per second (MS/s), and a sampling bandwidth is 0.01 MHz-10 MHz, which can meet the requirements of high-frequency sampling of the partial discharge pulse signal.

Specifically, each of the two high-frequency current transformers may adopt a split structure, which is convenient for the two high-frequency current transformers to install at grounding coils at the two ends of the high-voltage cable. During installation, a primary winding of each high-frequency current transformer is wound on a grounding wire of the high-voltage cable, and a secondary winding of each high-frequency current transformer is connected to a data acquisition device through a coaxial cable. The data acquisition device acquires an analog signal, and then a high-speed analog-to-digital converter (ADC) converts the analog signal to obtain a digital signal, and transmits the digital signal to a data processor.

In a practical application, the two high-frequency current transformers simultaneously collect the partial discharge pulse signal at the two ends of the high-voltage cable, and the collected signal has characteristic information such as an amplitude, a phase and a waveform of the partial discharge pulse signal. Because the partial discharge pulse signal has the characteristics of higher frequency and narrower pulse, using higher sampling rate and higher precision sampling method can accurately capture rapid change characteristics of the partial discharge pulse signal and provide reliable original data for subsequent signal processing and analysis.

Specifically, in an embodiment of the present disclosure, the step S2 includes steps S21 through S25.

In the step S21, a wavelet basis function is determined for the partial discharge pulse signal. According to characteristics of the partial discharge pulse signal, a wavelet basis function with a good time-frequency localization characteristic, such as an orthogonal wavelet base function such as daubechies 4-tap wavelet (db4), or symlets 4-tap wavelet (sym4), is determined for the partial discharge pulse signal. These wavelet basis functions are compactly supported and symmetrical, and are suitable for dealing with transient characteristics in the partial discharge pulse signal.

In the step S22, n-level wavelet decomposition is performed by using the wavelet basis function on the partial discharge pulse signal to obtain an approximation coefficient an and detail coefficients d₁-dₙ.

The step S22 further includes: determining an optimal decomposition scale n based on signal frequency features of the partial discharge pulse signal, a calculation formula for the optimal decomposition scale n is expressed as follows:

$$n = floor ( {log}_{2} ( \frac{{f}_{s}}{{f}_{m i n}} ) )$$

where fₛ represents a sampling frequency, fₘᵢₙ represents a lowest frequency of interest, and floor represents a floor function. This method for determining the optimal decomposition scale n can ensure that the determined decomposition scale matches the signal frequency features of the partial discharge pulse signal and improve a noise reduction effect.

Specifically, in an embodiment, during performing the n-level wavelet decomposition, a pyramid algorithm may be used, and the partial discharge pulse signal is decomposed recursively through a high-pass filter and a low-pass filter, so that the partial discharge pulse signal is fully represented in different frequency bands.

In the step S23, a signal-to-noise ratio SNRⱼ for a detail coefficient corresponding to a j-th level of the detail coefficients d₁-dₙ is calculated based on the following formula:

$$S N {R}_{j} = 10 {log}_{10} ( \frac{{σ}_{sj}^{2}}{{σ}_{nj}^{2}} )$$

where

$${σ}_{sj}^{2}$$

represents a signal variance for the j-th level

$${σ}_{nj}^{2}$$

represents a noise variance for the j-th level, j represents a decomposition level number, and j=1, 2, . . . , n.

In the step S24, an adaptive weight coefficient calculation model is established to determine an adaptive weight coefficient of each level, which is expressed as follows:

$${w}_{j} = \frac{{SNR}_{j}}{max ( {SNR}_{1} , {SNR}_{2} , … , {SNR}_{n} )}$$

where wⱼ represents an adaptive weight coefficient for the j-th level. The adaptive weight coefficient calculation model automatically assigns weights for the n levels according to the signal-to-noise ratio of each level, so that the level with higher signal-to-noise ratio has greater weight, thus retaining more useful signal components.

In the step S25, wavelet reconstruction is performed based on the adaptive weight coefficient of each level and the detail coefficient of each level and according to a reconstruction signal model, to obtain the denoised partial discharge characteristic signal, and the reconstructed signal model is expressed as follows:

$$Y ( t ) = \sum ( {w}_{j} \cdot {T}_{j} ( {d}_{j} ) )$$

where Y(t) represents a reconstructed signal, i.e., the denoised partial discharge characteristic signal, and Tⱼ(dⱼ) represents a threshold function for the j-th level. The threshold function is a soft threshold function, and is expressed as follows:

$${T}_{j} ( {d}_{j} ) = sign ( {d}_{j} ) ( \vert {d}_{j} \vert - {λ}_{j} ) , \vert {d}_{j} \vert > {λ}_{j}$$

$${T}_{j} ( {d}_{j} ) = 0 , \vert {d}_{j} \vert \leq {λ}_{j}$$

where λⱼ represents an adaptive threshold for the j-th level, and a formula for λⱼ is expressed as follows:

$${λ}_{j} = {σ}_{j} \cdot {( 2 ln N )}^{0.5}$$

where σⱼ represents a noise standard deviation of the j-th level, and N represents a signal length, i.e., a length of the partial discharge pulse signal. The soft threshold function can smooth the signal and avoid the discontinuity caused by a hard threshold function.

The reconstruction process in this embodiment comprehensively considers a weight and a threshold processing result of a signal corresponding to each level, which can effectively preserve the discharge characteristics and suppress the background noise.

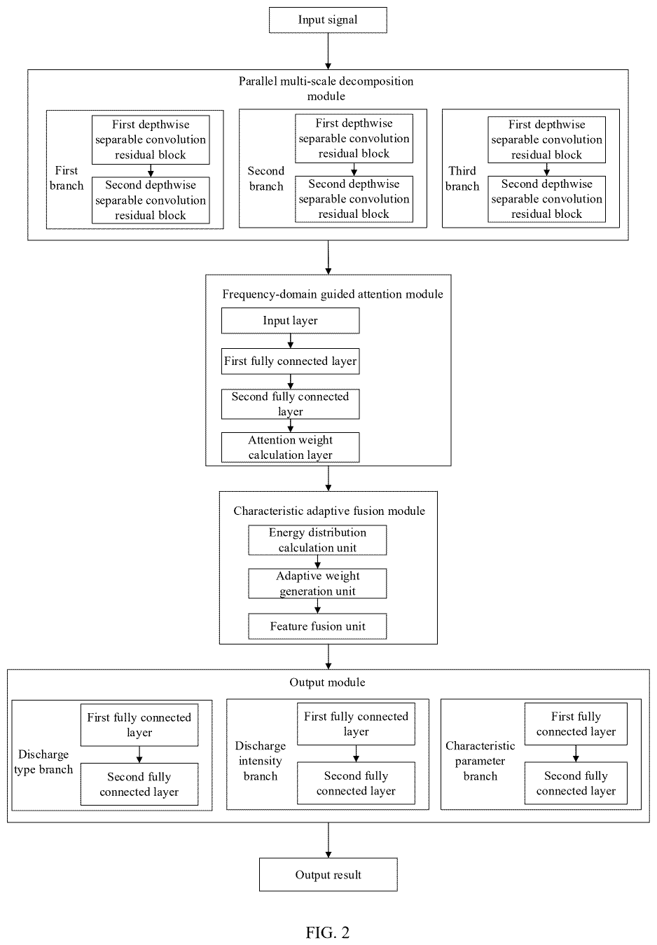

Specifically, as shown in FIG. 2, in an embodiment of the present disclosure, the lightweight residual attention network includes: a parallel multi-scale decomposition module, a frequency-domain guided attention module, a characteristic adaptive fusion module, and an output module.

The parallel multi-scale decomposition module includes three parallel branches, i.e., a first branch, a second branch, and a third branch, and each of the three parallel branches includes two depthwise separable convolutional residual blocks. The first branch has a 3×3 convolution kernel, a stride of 1, and 64 channels, and is used to capture local fine-grained characteristics of the partial discharge pulse signal. The second branch has a 5×5 convolution kernel, a stride of 1, and 32 channels, and is used to capture medium-scale characteristic of the partial discharge pulse signal. The third branch has a 7×7 convolution kernel, a stride of 1, and 16 channels, and is used to capture large-scale contextual characteristics of the partial discharge pulse signal. Each convolutional residual block includes two layers of depthwise separable convolution and a skip connection and is used to capture feature information at different scales.

Specifically, each convolutional residual block is configured as follows:
a first layer of depthwise separable convolution: pointwise convolution+depthwise convolution, a batch normalization (BN) layer, a rectified linear unit (ReLU) activation function;
a second layer of depthwise separable convolution: pointwise convolution+depthwise convolution, a BN layer;
the skip connection, configured to add an input feature to an output of the second layer of depthwise separable convolution; and
an output activation: an ReLU function.

The frequency-domain guided attention module includes: an input layer, configured to receive characteristic maps respectively outputted by the three parallel branches; and two fully connected layers and an attention weight calculation layer, configured to extract and strengthen a frequency domain characteristic. The frequency-domain guided attention module may further include a frequency-domain transformation layer, which is arranged behind the input layer and configured to perform two-dimensional Fourier transform on the characteristic maps. Specifically, the attention weight calculation layer includes: a channel attention branch, which is configured to generate an attention weight of channel dimension; a spatial attention branch, which is configured to generate an attention weight of spatial dimension; and an attention fusion, which is configured to fuse a channel attention with a spatial attention.

The characteristic adaptive fusion module includes: an energy distribution calculation unit, which is configured to calculate an energy distribution of each of the characteristic maps of the three parallel branches; an adaptive weight generation unit, which is configured to output fusion weights of the three parallel branches; and a feature fusion unit, which is configured to perform a concatenate operation on weighted features.

The output module includes three task branches, the three task branches are a discharge type branch, a discharge intensity branch, and a characteristic parameter branch, and each of the three task branches includes two fully connected layers.

A process for processing the partial discharge characteristic signal by the lightweight residual attention network is as follows.

The partial discharge characteristic signal is inputted into the parallel multi-scale decomposition module, and the three parallel branches simultaneously process the partial discharge characteristic signal, and each branch outputs a characteristic map of a corresponding scale. For an input signal x, a process on the input signal x by an i-th branch can b expressed as

$${F}_{i} ( x ) = {H}_{i}^{2} ( {H}_{i}^{1} ( x ) ) + x ,$$

where

$${H}_{i}^{1}$$

represents a first depthwise separable convolution residual block of the i-th branch,

$${H}_{i}^{2}$$

represents a second depthwise separable convolution residual block of the i-th branch and three characteristic maps at different scales are obtained, i.e., {F₁(x),F₂(x),F₃(x)}.

The three characteristic maps outputted by the parallel multi-scale decomposition module are inputted into the frequency-domain guided attention module. The input layer of the frequency-domain guided attention module is configured to calculate a spectral characteristic S(F)=FFT(F) through fast Fourier transform. The two fully connected layers of the frequency-domain guided attention module are configured to extract a frequency domain characteristic V=W₂·ReLU(W₁·S(F)), where W₁ and W₂ represent weight matrixes of the two fully connected layers of the frequency-domain guided attention module, respectively, and output dimensions of the two fully connected layers are 128 and 64, respectively. The attention weight calculation layer is configured to generate attention weights, output a weight matrix A=sigmoid(V) that has the same dimensions as the three characteristic maps, and weight the three characteristic maps based on the weight matrix A=sigmoid(V) to obtain weighted characteristic maps Fᵢ(x)=Fᵢ(x)⊙A, where ⊙ represents element-wise multiplication.

The weighted characteristic maps are inputted into the characteristic adaptive fusion module, and the characteristic adaptive fusion module is configured to: calculate a feature energy of each characteristic map according to the following formula: Eᵢ=∥Fᵢ(x)∥₂; calculate fusion weights based on the feature energy of each characteristic map according to the following formula: wᵢ=softmax(Eᵢ), and perform, based on the fusion weights and the weighted characteristic maps, weighted fusion to obtain a final feature representation F*=concat(w₁·F₁(x),w₂·F₂(x),w₃·F₃(x)).

The final feature representation is used as a shared feature, and is inputted into the output module and processed through the three task branches.

For the discharge type branch: the shared feature is inputted into a first fully connected layer with 128 neurons of the discharge type branch to obtain a first output result, an ReLU function of the discharge type branch is used to activate the first output result to obtain a first activated result, then the first activated result is inputted into a second fully connected layer with a total number of neurons equal to a total number of discharge types of the discharge type branch to obtain a second output result, a softmax function of the discharge type branch is used to activate the second output result to obtain a second activated result to output a probability distribution of each of the discharge types, and a discharge type with a highest probability of the discharge types is determined as the discharge type discrimination result.

For the discharge intensity branch: the shared feature is inputted into a first fully connected layer with 128 neurons of the discharge intensity branch to obtain a third output result, an ReLU function of the discharge intensity branch is used to activate the third output result to obtain a third activated result, and then the third activated result is inputted into a second fully connected layer with a single neuron of the discharge intensity branch to obtain a fourth output result, and a linear activation function of the discharge intensity branch is used to activate the fourth output result to obtain an intensity value as the discharge intensity.

For the characteristic parameter branch: the shared feature is inputted into a first fully connected layer with 128 neurons of the characteristic parameter branch to obtain a fifth output result, an ReLU function of the characteristic parameter branch is used to activate the fifth output result to obtain a fifth activated result, and then the fifth activated result is inputted into a second fully connected layer with a total number of neurons equal to a total number of characteristic parameters of the characteristic parameter branch to obtain a sixth output result, and a linear activation function of the characteristic parameter branch is used to activate the sixth output result to obtain parameter values as the characteristic parameters.

Specifically, in an embodiment, a pre-training process of the lightweight residual attention network is as follows.

The lightweight residual attention network adopts an end-to-end training mode, and an Adam optimizer is used for parameter optimization. A learning rate is initially set to 0.001, and is dynamically adjusted using a cosine annealing strategy. In order to fully consider the particularity of the partial discharge signal, an adaptive multi-task loss function based on frequency domain energy distribution is designed as follows:

$$L = {L}_{type} + {λ}_{1} \cdot {L}_{strength} + {λ}_{2} \cdot {L}_{param} + {λ}_{3} \cdot {L}_{freq}$$

where L_{type} represents a discharge type classification loss and employs a cross-entropy loss with a frequency-domain energy weight, and is expressed as follows:

$${L}_{type} = - \sum ( {y}_{i} \cdot log ( {p}_{i} ) \cdot {w}_{i} )$$

$${w}_{i} = \frac{{E}_{i}}{\sum {E}_{i}}$$

where yᵢ represents a one-hot encoding of a true label, Pᵢ represents a probability distribution predicted by the lightweight residual attention network, wᵢ represents frequency-domain energy weight, and Eᵢ represents an energy of an i-th class of samples in a target frequency band;
where L_{strength} represents a discharge strength regression loss, and considers characteristics of signal amplitude distribution, and is expressed as follows:

$${L}_{strength} = MSE ( {y}_{1} , ) \cdot ( 1 + α \cdot \frac{\vert FFT ( {y}_{1} ) - FFT ( ) \vert}{‖ FFT ( {y}_{1} ) ‖} )$$

where y₁ represents a true discharge strength value, [symbol] represents a predicted discharge strength value, a represents a weight coefficient for frequency-domain difference, and each of FFT(y) and FFT(ŷ) represents Fourier transform;
where Lₚₐᵣₐₘ represents a characteristic parameter regression loss, which incorporates a correlation constraint between parameters, and is expressed as follows:

$${L}_{param} = MSE ( {y}_{2} , ) + β \cdot \sum \vert Corr ( {y}_{2}^{i} , {y}_{2}^{i} ) - Corr ( {\hat{y}}_{2}^{i} , {\hat{y}}_{2}^{i} ) \vert$$

where y₂ represents a true characteristic parameter vector, [symbol] represents a predicted characteristic parameter vector, β represents a weight for correlation constraint, and

$$Corr ( {y}_{2}^{i} , {y}_{2}^{i} )$$

represents a Pearson correlation coefficient between parameters;
where L_{freq} represents a frequency-domain consistency loss, ensuring performance of the lightweight residual attention network in the frequency domain, and is expressed as follows:

$${L}_{freq} = KL ( PSD ( {y}_{3} ) , PSD ( {\hat{y}}_{3} ) )$$

where PSD(y₃) represents a power spectral density of a true signal, PSD(ŷ₃) represents a power spectral density of a predicted signal, and KL represents a Kullback-Leibler divergence, used to measure a difference between two probability distributions;
λ₁, λ₂, and λ₃ represents weighting coefficients for terms of the adaptive multi-task loss function, each of which has a value in a range of [0, 1]. Initial values thereof are set as λ₁==0.4, λ₂=0.3, and λ₃=0.3.

During the training of the above network, a parameter dynamic adjustment strategy is adopted and is described as follows.

The initial learning rate is set to 0.001, a cosine annealing cycle is 10 epochs, and a minimum learning rate is 10⁻⁶. The learning rate restarts if a validation loss fails to decrease for 3 consecutive epochs. Based on the validation set performance, the weight coefficients are updated after each epoch. If the decrease rate of a specific loss term is significantly slower than others, a corresponding value λ is increased. Conversely, if a loss term decreases too rapidly, potentially leading to overfitting, the corresponding value λ is decreased. The adjustment step size is ±0.05, to ensure λ₁+λ₂+λ₃=1.

Once the lightweight residual attention network is trained, it can be deployed on an embedded processor, such as an advanced RISC machine (ARM) Cortex-A72 or a higher-performance processor. After collecting the partial discharge pulse signal using the high-frequency current transformers, noise reduction processing is performed on the partial discharge pulse signal to obtain a denoised partial discharge characteristic signa, and the denoised partial discharge feature signal is input into the trained lightweight residual attention network for identification and classification to thereby output a discharge type discrimination result, a discharge intensity, and characteristic parameters.

In this embodiment, the discharge type classification includes three categories: internal discharge, surface discharge, and corona discharge. The discharge type branch outputs a probability distribution vector using a softmax activation function, indicating a likelihood of each of the three categories. For example: internal discharge: 0.85 (85%); surface discharge: 0.10 (10%); corona discharge: 0.05 (5%). In this case, the pre-trained lightweight residual attention network determines that the partial discharge pulse signal is most likely an internal discharge, with a confidence level of 85%.

In this embodiment, the discharge strength branch outputs a single numerical value using a linear activation function, representing a magnitude of a discharge quantity in units of picocoulomb (pC). For example, the detected discharge strength might be 500 pC.

In this embodiment, the characteristic parameter branch outputs a multi-dimensional vector using a linear activation function, representing various characteristic parameters of the partial discharge pulse signal. These characteristic parameters include a rise time, a duration, a waveform, a main frequency, and an amplitude. For example: rise time: 0.5 s; duration: 2.5 s; waveform feature: 0.75; main frequency: 2.5 MHz; and amplitude feature: 0.85. These parameters are used to describe the time-domain and frequency-domain characteristics of the partial discharge pulse signal.

Specifically, in an embodiment of the present disclosure, the step S4 includes steps S41 through S44.

In the step S41, propagation speed correction coefficients are determined according to the discharge type discrimination result, and a propagation speed is corrected based on the propagation speed correction coefficients and a discharge intensity coefficient. The propagation speed correction coefficients include a discharge type correction coefficient and a discharge intensity correction coefficient. A formula for correcting the propagation speed is expressed as follows:

$$v = {v}_{0} \cdot ( 1 + {k}_{1} \cdot type + {k}_{2} \cdot strength )$$

where ν represents a corrected propagation speed, ν₀ represents a theoretical propagation speed of the partial discharge pulse signal in the high-voltage cable, k₁ represents the discharge type correction coefficient, k₂ represents the discharge intensity correction coefficient, type represents a discharge type coefficient, and strength represents a discharge intensity coefficient. A value of the discharge type coefficient type is 1.0 for internal discharge, is 0.8 for surface discharge, or is 0.6 for corona discharge.

A calculation formula for the discharge intensity coefficient strength is expressed as follows:

$$strength = min ( 1. , q / {q}_{0} )$$

where q represents an actual discharge intensity, and q₀ represents a theoretical discharge intensity threshold.

Specifically, a value of k₁ is in a range of 0.1 to 0.3, which considers the influence of different discharge types on the propagation speed, the internal discharge has the greatest influence and the corona discharge has the least influence. A value of k₂ is in a range of 0.2 to 0.4, which considers the influence of discharge intensity on propagation speed, it keeps a reasonable proportional relationship with k₁.

In the step S42, a signal propagation model is established based on a main frequency feature, an amplitude feature and a waveform feature of the partial discharge pulse signal to calculate a comprehensive correction term, where the signal propagation model considers influence of multiple factors. A calculation formula for the comprehensive correction term is expressed as follows:

$$δ = α \cdot freq + β \cdot amp + γ \cdot shape$$

where δ represents the comprehensive correction term, freq represents the main frequency feature of the partial discharge pulse signal, amp represents the amplitude feature of the partial discharge pulse signal, shape represents the waveform feature of the partial discharge pulse signal, and α, β, and γ are weight coefficients of the main frequency feature, the amplitude feature, and the waveform feature, respectively.

Specifically, because the main frequency feature has the greatest influence on the positioning accuracy, and the main frequency feature is relatively stable and reliable, while the amplitude feature is secondary, and the waveform feature is relatively unstable due to the influence of signal attenuation, which is greatly influenced by the propagation process.

Therefore, when setting α, β, and γ, recommended values are used for initial setting, fine-tuning for α, β, and γ is carried out according to actual test results, and the constraint α+β+γ=1 is maintained, and α>p>γ.

In the step S43, timestamps of the partial discharge pulse signal arrival at the two ends of the high-voltage cable are collected by a global positioning system (GPS) high-precision time synchronization system, and a maximum value point of a cross-correlation function of signals at the two ends is calculated based on the timestamps to obtain a precise time difference. A calculation formula for the precise time difference is expressed as follows:

$$τ = arg max \{ {R}_{12} ( t ) \}$$

where τ represents the precise time difference, R₁₂(t) represents cross-correlation function of collected signals at the two ends, R₁₂(t)=∫x₁(τ)x₂(τ−t)dτ, x₁(τ) represents a signal collected at a first end of the two ends, x₂(τ) represents a signal collected at a second end of the two ends, t represents a time delay value to be tried, x₂(τ−t) represents a signal obtained by moving the signal collected at the second end to the right by t time units.

In the step S44, based on the length parameter of the high-voltage cable, the corrected propagation speed, and the precise time difference, the position of the discharge source is calculated. A calculation formula for the position of the discharge source is expressed as follows:

$$d = \frac{L + τ \cdot v}{2} + δ$$

where d represents a distance from a partial discharge point to a reference end, and L represents a total length of the high-voltage cable.

According to the present disclosure, a dual-end high-precision positioning technology based on GPS timing is adopted, a high-frequency current transformer and a high-speed sampling device are installed at each end of the high-voltage cable, and a 3 ns precision time synchronization signal provided by Beidou GPS is utilized to synchronously collect a partial discharge pulse signal. Firstly, a system corrects a propagation speed according to a discharge type and a discharge intensity. Then based on a main frequency feature, an amplitude feature and a waveform feature of the partial discharge pulse signal, a comprehensive correction term is calculated. Then, a precise time difference of signals acquired at two ends of the high-voltage cable is calculated by cross-correlation analysis. Finally, based on a length parameter L of the high-voltage cable, a position of a discharge source is calculated, in which, a positioning accuracy can reach 0.20% L±5 m. In a whole process, a field-programmable gate array (FPGA) and high-speed ADC are used for real-time data processing, and a positioning result, i.e., the position of the discharge source is uploaded to a background server in real time through a 4th generation (4G) wireless network.

The above is merely illustrated embodiments of the present disclosure, and it is not used to limit the present disclosure. Any modification, equivalent substitution, and improvement made within the spirit and principle of the present disclosure should be included in the scope of protection of the present disclosure.

What is claimed is:

1. A method for identifying and positioning partial discharge of a high-voltage cable, wherein the method comprises the following steps:
S1, collecting, by high-frequency current transformers respectively disposed two ends of the high-voltage cable, a partial discharge pulse signal;
S2, performing noise reduction processing on the partial discharge pulse signal by using an adaptive multi-scale wavelet decomposition and reconstruction method to obtain a denoised partial discharge characteristic signal;
S3, inputting the denoised partial discharge characteristic signal into a pre-trained lightweight residual attention network for identification and classification to thereby output a discharge type discrimination result, a discharge intensity, and characteristic parameters, wherein the lightweight residual attention network comprises a parallel multi-scale decomposition module, a frequency-domain guided attention module, a characteristic adaptive fusion module, and an output module;
wherein the lightweight residual attention network comprises:
a parallel multi-scale decomposition module, wherein the parallel multi-scale decomposition module comprises three parallel branches, the three parallel branches are a first branch, a second branch, and a third branch, and each of the three parallel branches comprises two depthwise separable convolutional residual blocks; the first branch has a 3×3 convolution kernel, a stride of 1, and 64 channels; the second branch has a 5×5 convolution kernel, a stride of 1, and 32 channels; the third branch has a 7×7 convolution kernel, a stride of 1, and 16 channels; and each of the two depthwise separable convolutional residual blocks of each of the three parallel branches comprises two layers of depthwise separable convolution and one skip connection;
a frequency-domain guided attention module, comprising: an input layer, two fully connected layers, and an attention weight calculation layer;
a characteristic adaptive fusion module, comprising: an energy distribution calculation unit, configured to calculate an energy distribution of each of characteristic maps of the three parallel branches; an adaptive weight generation unit, configured to output fusion weights of the three parallel branches; and a feature fusion unit, configured to perform a concatenate operation on weighted features; and
an output module, comprising three task branches, wherein the three task branches are a discharge type branch, a discharge intensity branch, and a characteristic parameter branch, and each of the three task branches comprises two fully connected layers;
wherein a process for processing the partial discharge characteristic signal by the lightweight residual attention network comprises:
inputting the partial discharge characteristic signal into the parallel multi-scale decomposition module, processing, by the three parallel branches, the partial discharge characteristic signal simultaneously, and outputting, by each of the three parallel branches, a corresponding one characteristic map of the characteristic maps with a corresponding scale;
inputting the characteristic maps outputted by the parallel multi-scale decomposition module into the frequency-domain guided attention module; calculating, by the input layer of the frequency-domain guided attention module, a spectral characteristic through fast Fourier transform; extracting, by the two fully connected layers of the frequency-domain guided attention module, a frequency domain feature, where output dimensions of the two fully connected layers are 128 and 64, respectively; generating, by the attention weight calculation layer, attention weights and outputting a weight matrix with the same dimensions as the input characteristic maps; and weighting, by the attention weight calculation layer, the characteristic maps based on the weight matrix to obtain weighted characteristic maps;
inputting the weighted characteristic maps into the characteristic adaptive fusion module, calculating, by the characteristic adaptive fusion module, a feature energy of each of the characteristic maps of the three parallel branches, calculating, by the characteristic adaptive fusion module, the fusion weights based on the feature energy of each of the characteristic maps, and performing, by the characteristic adaptive fusion module, weighted fusion to obtain a final feature representation; and
using the final feature representation as a shared feature, inputting the shared feature into the output module, and processing the shared feature through the three task branches of the output module, respectively, wherein the processing the shared feature through the three task branches of the output module comprises:
for the discharge type branch: inputting the shared feature into a first fully connected layer with 128 neurons of the discharge type branch to obtain a first output result, using a rectified linear unit (ReLU) function of the discharge type branch to activate the first output result to obtain a first activated result, inputting the first activated result into a second fully connected layer with a total number of neurons equal to a total number of discharge types of the discharge type branch to obtain a second output result, using a softmax function of the discharge type branch to activate the second output result to obtain a second activated result to output a probability distribution of each of the discharge types, and determining a discharge type with a highest probability of the discharge types is determined as the discharge type discrimination result;
for the discharge intensity branch: inputting the shared feature into a first fully connected layer with 128 neurons of the discharge intensity branch to obtain a third output result, using an ReLU function of the discharge intensity branch to activate the third output result to obtain a third activated result, inputting the third activated result into a second fully connected layer with a single neuron of the discharge intensity branch to obtain a fourth output result, and using a linear activation function of the discharge intensity branch to activate the fourth output result to obtain an intensity value as the discharge intensity; and
for the characteristic parameter branch: inputting the shared feature into a first fully connected layer with 128 neurons of the characteristic parameter branch to obtain a fifth output result, using an ReLU function of the characteristic parameter branch to activate the fifth output result to obtain a fifth activated result, inputting the fifth activated result into a second fully connected layer with a total number of neurons equal to a total number of characteristic parameters of the characteristic parameter branch to obtain a sixth output result, and using a linear activation function of the characteristic parameter branch to activate the sixth output result to obtain parameter values as the characteristic parameters; and
S4, using, based on the discharge type discrimination result, the discharge intensity, and the characteristic parameters, a self-correcting dual-end localization algorithm to position a discharge source, comprising: measuring a time difference of arrival of the partial discharge pulse signal at the two ends of the high-voltage cable, and calculating, based on the time difference, the discharge type discrimination result, the discharge intensity, the characteristic parameters, and a length parameter of the high-voltage cable, a position of the discharge source, wherein the step S4 comprises:
S41, determining propagation speed correction coefficients according to the discharge type discrimination result, and correcting, based on the propagation speed correction coefficients and a discharge intensity coefficient, a propagation speed;
S42, establishing, based on a main frequency feature, an amplitude feature and a waveform feature of the partial discharge pulse signal, a signal propagation model considering multi-factor influences to calculate a comprehensive correction term;
S43, acquiring, by a global positioning system (GPS) high-precision time synchronization system, timestamps of the partial discharge pulse signal arrival at the two ends of the high-voltage cable, calculating, based on the timestamps, a maximum value point of a cross-correlation function of signals collected at the two ends to obtain a precise time difference; and
S44, calculating the position of the discharge source based on the length parameter of the high-voltage cable, the corrected propagation speed, and the precise time difference.

2. The method for identifying and positioning partial discharge of the high-voltage cable as claimed in claim 1, wherein the step S2 comprises:
S21, determining a wavelet basis function for the partial discharge pulse signal;
S22, performing, by using the wavelet basis function, n-level wavelet decomposition on the partial discharge pulse signal to obtain an approximation coefficient αₙ and detail coefficients d₁-dₙ;
S23, calculating a signal-to-noise ratio SNRⱼ for a detail coefficient corresponding to each of n levels based on the following formula:
$${SNR}_{j} = 10 {log}_{10} ( \frac{{σ}_{sj}^{2}}{{σ}_{nj}^{2}} )$$
where
$${σ}_{sj}^{2}$$
represents a signal variance
$${σ}_{nj}^{2}$$
represents a noise variance, j represents a decomposition level number, and j=1, 2, . . . , n;
S24, establishing an adaptive weight coefficient calculation model, wherein the adaptive weight coefficient calculation model is expressed as follows:
$${w}_{j} = \frac{{SNR}_{j}}{max ( {SNR}_{1} , {SNR}_{2} , … , {SNR}_{n} )}$$
where wⱼ represents an adaptive weight coefficient; and
S25, performing, based on the adaptive weight coefficient of each level and the detail coefficient of each level and according to a reconstruction signal model, wavelet reconstruction to obtain the denoised partial discharge characteristic signal, wherein the reconstruction signal model is expressed as follows:
$$Y ( t ) = \sum ( {w}_{j} \cdot {T}_{j} ( {d}_{j} ) )$$
where _{Y(t)} represents a reconstructed signal, and _{T}_{ⱼ}_{(d}_{ⱼ}₎ represents a threshold function.

3. The method for identifying and positioning partial discharge of the high-voltage cable as claimed in claim 2, wherein the threshold function Tⱼ(dⱼ) is a soft threshold function, and the soft threshold function is expressed as follows:
$${T}_{j} ( {d}_{j} ) = sign ( {d}_{j} ) ( \vert {d}_{j} \vert - {λ}_{j} ) , \vert {d}_{j} \vert > {λ}_{j}$$
$${T}_{j} ( {d}_{j} ) = 0 , \vert {d}_{j} \vert \leq {λ}_{j}$$
where λⱼ represents an adaptive threshold for a j-th level, and a formula for λⱼ is expressed as follows:
$${λ}_{j} = {σ}_{j} \cdot {( 2 ln N )}^{0.5}$$
where σⱼ represents a noise standard deviation for the j-th level, and N represents a signal length.

4. The method for identifying and positioning partial discharge of the high-voltage cable as claimed in claim 2, wherein the step S2 further comprises:
determining an optimal decomposition scale n based on signal frequency features of the partial discharge pulse signal, wherein a calculation formula for the optimal decomposition scale n is expressed as follows:
$$n = floor ( {log}_{2} ( \frac{{f}_{s}}{{f}_{m i n}} ) )$$
where fₛ represents a sampling frequency, fₘᵢₙ represents a lowest frequency of interest, and floor represents a floor function.

5. The method for identifying and positioning partial discharge of the high-voltage cable as claimed in claim 1, wherein a formula for correcting the propagation speed is expressed as follows:
$$v = {v}_{0} \cdot ( 1 + {k}_{1} \cdot type + {k}_{2} \cdot strength )$$
where ν represents a corrected propagation speed, ν₀ represents a theoretical propagation speed of the partial discharge pulse signal in the high-voltage cable, k₁ represents a discharge type correction coefficient, k₂ represents a discharge intensity correction coefficient, type represents a discharge type coefficient, and strength represents a discharge intensity coefficient;
wherein a calculation formula for the precise time difference is expressed as follows:
$$τ = arg max \{ {R}_{12} ( t ) \}$$
where τ represents the precise time difference, R₁₂(t) represents the cross-correlation function of the signals at the two ends of the high-voltage cable, R₁₂(t)=∫x₁(τ)x₂(τ−t)dτ, x₁(τ) represents a signal collected at a first end of the two ends, x₂(τ) represents a signal collected at a second end of the two ends, t represents a time delay value to be tried, and x₂(τ−t) represents a signal obtained by moving the signal collected at the second end to the right by t time units;
wherein a calculation formula for the comprehensive correction term is expressed as follows:
$$δ = α \cdot freq + β \cdot amp + γ \cdot shape$$
where δ represents the comprehensive correction term, freq represents the main frequency feature of the partial discharge pulse signal, amp represents the amplitude feature of the partial discharge pulse signal, shape represents the waveform feature of the partial discharge pulse signal, and α, β, and γ are weight coefficients of the main frequency feature, the amplitude feature, and the waveform feature, respectively; and
wherein a calculation formula for the position of the discharge source is expressed as follows:
$$d = \frac{L + τ \cdot v}{2} + δ$$
where d represents a distance from a partial discharge point to a reference end, and L represents a total length of the high-voltage cable.

6. The method for identifying and positioning partial discharge of the high-voltage cable as claimed in claim 5, wherein the discharge type discrimination result is one of three categories: internal discharge, surface discharge, and corona discharge; and a value of the discharge type coefficient type is 1.0 for the internal discharge, is 0.8 for the surface discharge, or is 0.6 for the corona discharge; and
wherein a calculation formula for the discharge intensity coefficient strength is expressed as follows:
$$strength = min ( 1. , q / {q}_{0} )$$
where q represents an actual discharge intensity, and q₀ represents a theoretical discharge intensity threshold.

7. The method for identifying and positioning partial discharge of the high-voltage cable as claimed in claim 1, wherein each of the high-frequency current transformers has a sampling resolution of 14 bits, a sampling frequency of 10 mega samples per second (MS/s)−100 MS/s, and a sampling bandwidth of 0.01 MHz-10 MHz.
